(19) United States
(12) Patent Application Publication
(10) Pub. No.: US 2013/0052817 A1
(43) Pub. Date: Feb. 28, 2013

(54) METHOD FOR THE FABRICATION OF BONDING SOLDER LAYERS ON METAL BUMPS WITH IMPROVED COPLANARITY

(71) Applicant: Tim Hsiao, Tao Yuan Shien (TW)

(72) Inventor: Tim Hsiao, Tao Yuan Shien (TW)

(21) Appl. No.: 13/220,064

(22) Filed: Aug. 29, 2011

(51) Int. Cl. H01L 21/60

(52) U.S. Cl. 438/614; 257/E21.508

(57) ABSTRACT

A method for fabrication of bonding solder layers on metal bumps with improved coplanarity, applicable to the flip-chip bump bonding technique for semiconductor IC packaging. When metal bumps have different sizes, the bonding solders thereon may have different heights after high-temperature reflows. The present invention can improve the coplanarity of bonding solders, and mitigating or even eliminating the difficulties in downstream packaging and testing caused by the inconsistent height of bonding solders. To achieve this purpose, the present invention proposes a two-step fabrication method for controlling the surface areas of the metal bumps and the bonding solder layers thereon separately, and thereby improving the coplanarity of the bonding solders after high-temperature reflows. The two-step fabrication method includes: a first-step process for forming metal bumps on the semiconductor devices; and a second-step process for forming bonding solder layers of different sizes on the metal bumps.

### BACKGROUND OF THE INVENTION

1. Field of the invention

The present invention relates to a method for the fabrication of bonding solder layers on metal bumps with improved coplanarity, particularly to the processes for flip-chip bump bonding in semiconductor IC packaging technology.

2. Background of the invention

With the advances in semiconductor fabrication technology in recent years, the packaging technology for semiconductor chips has also been improved considerably. Traditionally, GaAs chips, such as power amplifier modules and RF components, are packaged by using the wire-bonding technique, i.e., using gold wires to interconnect the contact pads of all devices on a functional chip. In recent years, the wire-bonding technique has been gradually replaced by the flip-chip bump-bonding technique. The advantages of the flip-chip bump bonding technique include lower manufacturing cost, better flexibility on the connection design, and higher integration density after packaging, and therefore gradually becomes a major packaging technique in the GaAs IC technology.

The flip-chip bump bonding technique uses metal bumps instead of the conventional metallic bonding wires. FIGS. 1A to 1C are the schematic drawings for the process of fabricating metal bumps for the flip-chip bump bonding technique. First of all, the metal bump structures a2 are formed on the surface a1 of the contact pads of each devices. This step can be done by using the exposure and developing processes of the conventional photolithography technique commonly used in the semiconductor device processing to define the sizes and positions of the metal bumps, and then followed by metal deposition process to form the metal bump structure a2. The metal bump structure a2 can be composed of a single metal layer or multiple metal layers. Copper can be used as the material for the metal bumps because of its low cost and good electrical/thermal conductivity. After the formation of copper bump, a layer of bonding solder a3 is deposited thereon. The material for the bonding solder should have a lower melting temperature, such as tin, indium, or indium-tin based alloys. These solder materials can avoid using higher soldering temperatures during the bonding process, which is usually detrimental to the semiconductor devices. After high temperature treatments, the bonding solder layer starts to melt. The chip can then be soldered to the circuit board with interconnections among the contact points of all device components. However, as shown in FIG. 2A to 2C, when the sizes of copper bumps are different, the bonding solder on the bumps will reflow after high temperature treatments, forming island structure of different heights due to the surface tension of the solder. The solders with different height will lead to serious problems in the subsequent processes of soldering to the circuit board and hence degrade the packaging yield considerably.

In order to solve the problem in the flip-chip bump-bonding technique, it is necessary to develop a method for the fabrication of bonding solder layers on metal bumps with improved coplanarity, particularly when metal bumps on a semiconductor chip are of different sizes. The method should mitigate or even eliminate the problems caused by the bonding solders of different heights and hence facilitate the downstream packaging and testing.

### SUMMARY OF THE INVENTION

It is an object of the present invention to provide a method for fabricating bonding solder layers on metal bumps with improved coplanarity, and thereby mitigating or even eliminating the problems caused by the inconsistent height of the bonding solders after high-temperature treatments, particularly when the underlying metal bumps are of different sizes.

In order to achieve the abovementioned objects, the present invention proposes a two-step fabrication method, which control the surface areas of the metal bumps and the bonding solder layers separately to improve the coplanarity of the bonding solders after reflow, comprising steps of:

a first step process for forming the metal bump structures on the semiconductor devices; and

a second step process for forming the bonding solder layers of different sizes on the top surface of the said metal bump structures.

The first step process further comprises steps of:
coating or laminating a first photoresist layer over the surface of the semiconductor devices;
defining the sizes, shapes and positions of the metal bump structures by using the exposure and developing processes of the conventional photolithography technique;
depositing the material for forming the metal bump structure by using the metal deposition technique; and removing the first photoresist layer and forming the metal bump structures.

The second step process further comprises:
coating or laminating a second photoresist layer over the surface of the semiconductor devices and metal bump structures;
defining the sizes, shapes and positions of the bonding solder layers by using the exposure and developing processes of the conventional photolithography technique;
depositing the material for forming the bonding solder layer by using the metal deposition technique; and removing the second photoresist layer and forming the bonding solder layers on the metal bump structures.

The present invention will be understood more fully by reference to the detailed description of the drawings and the preferred embodiments below.

### BRIEF DESCRIPTION OF DRAWINGS

FIGS. 1A to 1C form a process flow diagram showing the fabrication process of metal bumps and bonding solder layers thereon for the flip-chip bump-bonding technology.

FIGS. 2A to 2C are schematic diagrams showing metal bumps with different lateral sizes and bonding solder layers thereon with different heights due to the solder reflow after high-temperature treatments.

FIGS. 3A to 3F are schematic diagrams showing the fabrication process of the bonding solder layer with improved coplanarity according to the embodiment of the present invention.

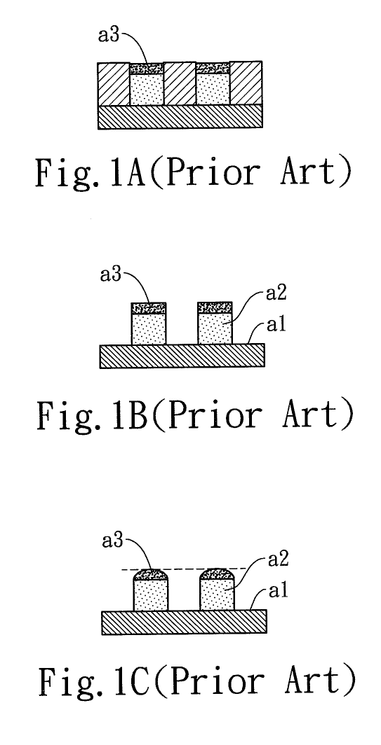

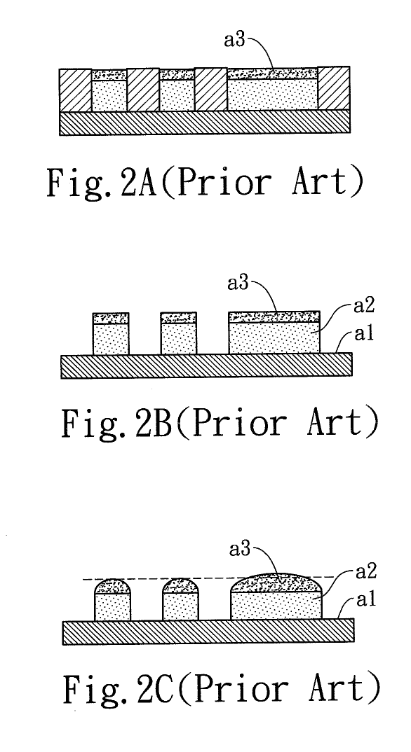

### DETAILED DESCRIPTION OF THE INVENTION

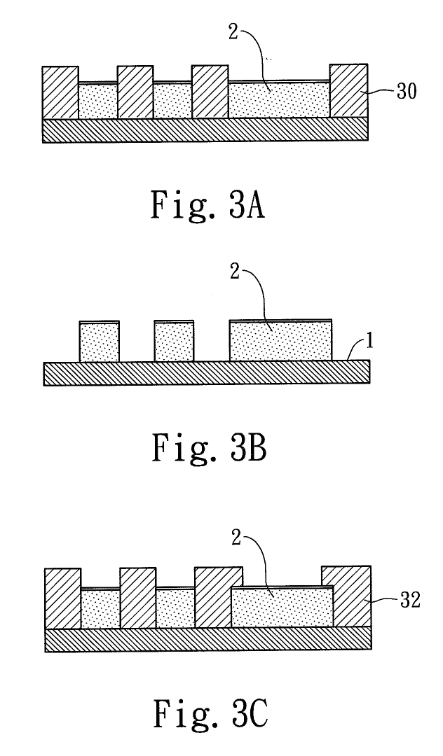

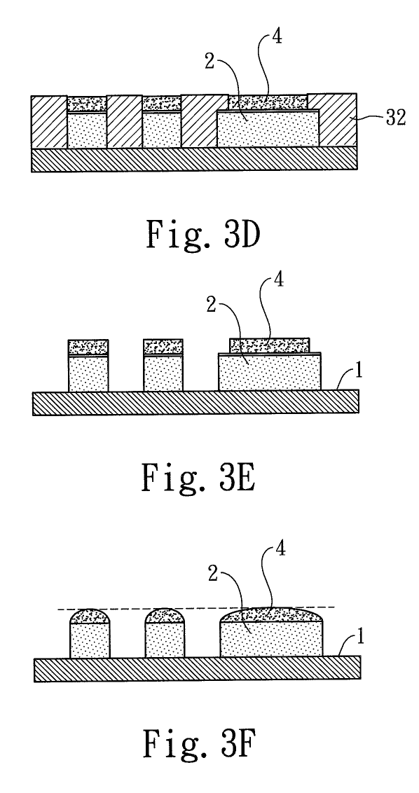

The inconsistent height of the bonding solder layers is due to the different sizes of underlying metal bumps and the surface tension of the bonding solder material; therefore, a proper control of the deposition area of the bonding solder layers can solve this problem. FIGS. 3A to 3F are schematic diagrams showing the fabrication process for the bonding solder layers with improved coplanarity according to the embodiment of the present invention. The present invention proposes a two-step process to control the surface areas of the metal bumps and the bonding solder layers separately, and thereby improving the coplanarity of bonding solders after reflow.

The purpose of the first step process of the present invention is to form metal bumps with different lateral sizes on the contact pads of semiconductor devices. In the first step process, a first photoresist layer 30 is coated or laminated over the surface of the semiconductor devices at first. The sizes, shapes and positions of the metal bump structures 2 are then defined by using the exposure and developing processes of the conventional photolithography technique. Then the material of the metal bump is deposited by using the metal deposition technique, as shown in FIG. 3A. Various metal deposition techniques can be used, depending on the metallic material to be used. They can be the sputtering, the thermal evaporation, or electroplating. Taking the copper bump structure as an example, the metal deposition can be done by using the electroplating technique. Finally, after removing the first photoresist layer 30, the copper bump structure will be formed on the contact pads of the semiconductor chip (as shown in FIG. 3B). To prevent the degradation in the electrical contacts between bumps and bonding solders caused by the surface oxidation of the bump metal during subsequent processes, a wetting layer can be deposited on the metal bumps by using the metal deposition technology in the first step process before removing the first photoresist layer. This procedure can also improve the wetting of the bonding solder on the bump metal.

After completing the first step process, the second step process can be conducted for depositing the bonding solder layers on the surface of the metal bumps or the wetting layer. In the second step process, as shown in FIG. 3C, a second photoresist layer 32 is first coated or laminated over the surface of the semiconductor devices 1 and the metal bumps 2. The positions and sizes of bonding solder layers are then defined by using the exposure and developing processes of the conventional photolithography techniques. Then a bonding solder layer 4 is deposited, as shown in FIG. 3D. The materials with lower melting temperature, such as tin, indium, tin-based alloys, or indium-based alloys are usually used as the solder material in order to prevent the device degradations after high temperature soldering processes.

Finally, as shown in FIGS. 3E and 3F, the structure of metal bumps 2 with bonding solder layers 4 thereon will be formed after removing the second photoresist layer 32. The basic idea of the second step is to control the total volume of the bonding solder, so that the bonding solders are of similar height even after high-temperature treatments. The height of the bonding solders after reflow can be calculated beforehand by numerical simulations considering the surface area, the thickness, and the surface tension of the solder material. The bonding solder height can also be estimated via experiments. A database of the solder height with different surface areas and thicknesses after the high-temperature reflow can be established by using trial and error measurements. Thereby, appropriate surface area and thickness for the bonding solder layers can be determined according to the surface area of the metal bumps.

As described above, through the two-step process to control the surface areas of metal bumps and bonding solder layers separately, the present invention can achieve the expected goal of improving the coplanarity of the bonding solders after reflows, even when metal bumps are of different surface areas. The present invention is therefore highly applicable to mass production.

Although the present invention has been illustrated and described with respect to exemplary embodiment thereof, it should be understood by those skilled in the art that the foregoing and various other changes, omissions and additions may be made therein and thereto, without departing from the spirit and scope of the present invention.

What is claimed is:

1. A method for the fabrication of metal bumps and bonding solder layers comprising:
a first step process for forming metal bump structures on the surface of semiconductor devices; and
a second step process for forming bonding solder layers of different sizes on the said metal bump structures; wherein the said first step process further comprising steps of:
coating or laminating a first photoresist layer over the surface of the said semiconductor devices;
defining the positions and shapes of the said metal bump structures by using exposure and developing processes of the conventional photolithography;
depositing the material for forming the said metal bump structures by using metal deposition techniques; and
removing the first photoresist layer and forming the metal bump structures; and
wherein the said second step process further comprising steps of:
coating or laminating a second photoresist layer over the surface of the said semiconductor devices and said metal bump structures;
defining the positions and shape of the said bonding solder layers by using exposure and developing processes of the conventional photolithography;
depositing the material for forming the said bonding solder layers by using metal deposition techniques; and
removing the second photoresist layer and forming the bonding solder layers on the said metal bump structures.

2. The fabrication method as described in claim 1, wherein in the first step process further comprising a step of depositing a wetting layer by using metal deposition techniques before the step of removing the first photoresist layer.

3. The fabrication method as described in claim 1, wherein in the said metal deposition techniques in the first step process and the second step process include the sputtering, the thermal evaporation, and the electroplating techniques.

4. The fabrication method as described in claim 1, wherein in the positions and shapes of the said bonding solder layers are defined according to the positions and shape of the said metal bump structures.

5. The fabrication method as described in claim 1, wherein the material of the metal bumps is copper.

6. The fabrication method as described in claim 1, wherein the material of the metal bumps is gold.

7. The fabrication method as described in claim 1, wherein the material of the bonding solder layers is indium.

8. The fabrication method as described in claim 1, wherein the material of the bonding solder layers is tin.

9. The fabrication method as described in claim 1, wherein the material of the bonding solder layers is an indium-based alloy or a tin-based alloy.
